(19) United States
(12) Patent Application Publication
(10) Pub. No.: US 2023/0059454 A1
(43) Pub. Date: Feb. 23, 2023

(54) LOW TEMPERATURE SYNTHESIS OF NiAl THIN FILMS

(71) Applicant: Jagannathan Rajagopalan, Scottsdale, AZ (US)

(72) Inventor: Jagannathan Rajagopalan, Scottsdale, AZ (US)

(21) Appl. No.: 17/893,949

(22) Filed: Aug. 23, 2022

Related U.S. Application Data
(60) Provisional application No. 63/236,004, filed on Aug. 23, 2021.

(51) Int. Cl. C23C 14/34; C23C 14/18; C23C 14/58; C23C 14/04

(52) U.S. Cl. CPC C23C 14/3464; C23C 14/18; C23C 14/5806; C23C 14/042

(57) ABSTRACT

Contacting a multiplicity of seed crystals with an amorphous metallic alloy layer to form an amorphous precursor film or depositing an amorphous precursor film on a substrate and annealing the amorphous precursor film at a temperature between 50° C. and 400° C. to yield the metallic film with grains separated by grain boundaries.

### CROSS-REFERENCE TO RELATED APPLICATION

This application claims the benefit of U.S. Patent Application 63/236,004 filed on Aug. 23, 2021, which is incorporated herein by reference in its entirety.

### TECHNICAL FIELD

This invention relates to synthesis of NiAl thin films for barrier- and liner-free interconnects.

### BACKGROUND

Integrated circuits (ICs) typically have metal interconnects. Metal interconnects distribute signals between individual components (transistors, capacitors, etc) and provide ground and power connections. Metal interconnects are often formed of aluminum or copper, and typically have a liner or barrier layer that separates the metal from the surrounding dielectric material and prevents metal diffusion into and reaction with the dielectric material.

### SUMMARY

This disclosure describes the synthesis of equiatomic (1:1 atomic ratio) NiAl thin films with a grain diameter to thickness ratio of at least about 20 for use in barrier- and liner-free interconnects. The NiAl thin films can be synthesized at temperatures that are compatible with back-end-of-line (BEOL) processing requirements for IC fabrication. BEOL manufacturing processes involve connecting the individual IC components with a conductive (metal) material but are typically limited to temperatures below 400° C. in order to avoid damage to the IC chip.

Precursor NiAl films are formed by depositing NiAl in the amorphous state. Deposition of NiAl in the amorphous state is followed by crystallization, which may be mediated by seed crystals. Crystallization of the amorphous film can be controlled by selecting sputtering parameters, seed crystals and annealing temperatures to achieve large grain sizes. The temperatures used in the process are compatible with BEOL processing requirements.

Interconnects formed with the NiAl films described herein are advantageous over interconnects with copper as the interconnecting conductive metal for at least the following reasons. NiAl does not react with or leach into the dielectric medium and thus can be implemented without a liner or barrier. This saves space and decreases resistivity as IC dimensions are scaled down. The disclosed NiAl thin films have electromigration resistance and thermal stability that are superior to Cu as interconnect widths are scaled down. At least because the electron mean free path in NiAl films is lower than that of copper, interfacial electron scattering and hence resistivity is decreased relative to copper as the interconnect linewidths are decreased.

In a first general aspect, forming a metallic film includes contacting a multiplicity of seed crystals with an amorphous metallic alloy layer to form an amorphous precursor film and annealing the amorphous precursor film at a temperature between 50° C. and 400° C. to yield the metallic film with grains separated by grain boundaries.

Implementation of the first general aspect can include one or more of the following features.

Certain implementations further include disposing the multiplicity of seed crystals on a substrate before contacting the multiplicity of seed crystals with the amorphous metallic alloy layer. In some cases, contacting the multiplicity of seed crystals with the amorphous metallic alloy layer includes encapsulating the multiplicity of seed crystals between the amorphous metallic alloy layer and the substrate. In some implementations, the multiplicity of seed crystals is disposed on the substrate in a predetermined pattern using a mask. In certain cases, the substrate includes a silicon dioxide or a glass.

In some cases, contacting the multiplicity of seed crystals with the amorphous metallic alloy layer includes depositing the amorphous metallic alloy layer on the multiplicity of seed crystals. In certain implementations, contacting the multiplicity of seed crystals with the amorphous metallic alloy layer includes depositing the amorphous metallic layer on a substrate and depositing the multiplicity of seed crystals on the amorphous metallic layer. In some implementations, contacting the multiplicity of seed crystals with the amorphous metallic alloy layer further includes encapsulating the multiplicity of seed crystals on the amorphous metallic layer with an additional amorphous metallic layer. In some cases, contacting the multiplicity of seed crystals with the amorphous metallic alloy layer includes cooling the substrate before depositing the amorphous metallic layer on the substrate.

In some implementations, contacting the multiplicity of seed crystals with an amorphous metallic alloy layer includes co-depositing constituent elements of the amorphous metallic alloy layer. In certain implementations, co-depositing the constituent elements of the amorphous metallic alloy layer includes co-sputtering from separate targets made from the individual constituent elements of the amorphous metallic alloy layer. In some cases, forming the amorphous metallic alloy layer includes depositing a metallic alloy. In some implementations, depositing the metallic alloy includes sputtering the metallic alloy from a compound target including two constituent elements.

In certain implementations, the amorphous metallic alloy layer includes NiAl. In some cases, the grains have a diameter to thickness ratio of at least about 20. In some implementations, the multiplicity of seed crystals includes one or more of Cr, Fe, V, and Cu. In certain cases, annealing the amorphous precursor film occurs at a temperature between 150° C. and 300° C.

In some implementations, the annealing occurs in one or more stages. In certain implementations, the annealing in one of the one or more stages includes annealing for a length of time at a temperature between 50° C. and 400° C. In some implementations, the annealing occurs in at least two stages, and includes annealing for a first length of time at a first temperature between 50° C. and 400° C. and annealing for a second length of time at a second temperature between 50° C. and 400° C. In certain implementations, the first length of time and the second length of time are the same or different, and the first temperature and the second temperature are different. In some cases, the first length of time and the second length of time are the same or different, the first temperature and the second temperature are the same or different, and annealing for the first length of time and annealing for the second length of time is separated by cooling for a length of time.

In a second general aspect, forming a metallic film includes depositing an amorphous precursor film on a substrate and annealing the amorphous precursor film at a temperature between 50° C. and 400° C. to yield the metallic film with grains separated by grain boundaries.

Implementation of the second general aspect can include the following feature. In some cases, the grains have a diameter to thickness ratio of at least about 20.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A is a flow chart showing steps in a first process for synthesizing NiAl films. FIG. 1B is a schematic illustration showing cross-sectional and plan views of the steps in FIG. 1A.

FIG. 2 is a flow chart showing steps in a second process for synthesizing NiAl films.

### DETAILED DESCRIPTION

Cu interconnects in integrated circuits typically exhibit increases in line resistivity when linewidths decrease below 20 nm for at least two reasons. First, scattering of electrons at the interfaces can become predominant since the linewidth is smaller than the electron mean free path (EMFP) in Cu (39 nm). Second, the liner and barrier layers can occupy an increasing fraction of the line volume. Since the resistivity of the liner (Ta, Co, or Ru) and the barrier (TaN) is larger than that of Cu, the overall resistivity of the line increases. The resistivity increase associated with the liner and barrier can become steeper with further decreases in linewidth. Interconnect materials that do not require a liner, a barrier, or both can advantageously enable further downscaling of device dimensions.

NiAl can be advantageous for barrier- and liner-free interconnects for at least the following reasons. Bulk NiAl has a relatively low resistivity of 9 μOhm-cm at room temperature (RT). Single crystal NiAl has even lower resistivity (5.2 μOhm-cm). NiAl has an EMFP of 8.15 nm, which can lead to better resistivity scaling with decreasing linewidths compared to Cu. The high melting point (Tₘ=1638° C.) and large cohesive energy (679 kJ/mol) of NiAl can lead to improved electromigration resistance and suppress interdiffusion and adverse reactions with Si and SiO₂. Al₂O₃ also as a higher heat of formation (1678 kJ/mol) than SiO₂ (911 kJ/mol). Hence, Al atoms are likely to bond with O atoms at the NiAl/SiO₂ interface and form a passivation layer with good adhesion, obviating the need for a barrier or a liner.

As-deposited NiAl thin films have small grain sizes (less than 20 nm), which can lead to higher resistivity than bulk NiAl. Large grain diameters are advantageous at least because they decrease the number of boundaries and structural inhomogeneity between crystallized domains, decreasing the resistivity of the NiAl interconnection. Furthermore, due at least in part to its high Tₘ, annealing temperatures greater than 500° C. are typically needed to induce notable grain growth. Thus, annealing of as-deposited thin films is generally incompatible with back end of line (BEOL) processes, which have maximum temperature of around 400° C.

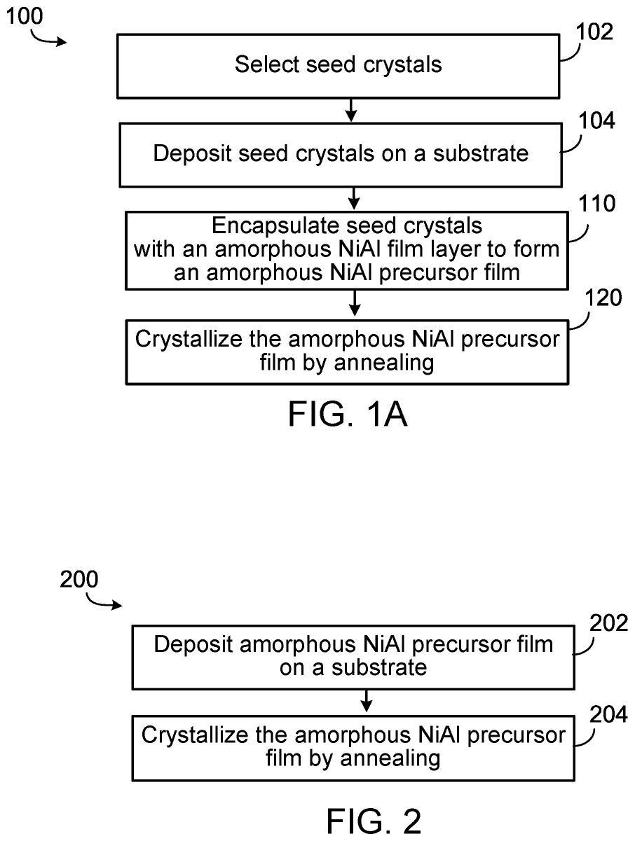

FIG. 1A depicts a process 100 for the synthesis of NiAl films with a grain diameter to thickness ratio of at least about 20 at temperatures (e.g., less than about 400° C. or less than about 300° C.) that are compatible with BEOL processes. FIG. 1B is a schematic illustration showing cross-sectional and plan views of the steps in FIG. 1A.

In 102, seed crystals are selected to promote nucleation of the B2 NiAl phase in an amorphous NiAl film during annealing. Examples of suitable materials for seed crystals include Fe, Cr, Cu, V, or a combination thereof. The seed crystals act as preferential grain nucleation sites, enabling epitaxial growth of NiAl and thus reducing the nucleation barrier. Selection of seed crystals is based at least in part on thermal stability and wettability. A larger spacing between the seed crystals leads to larger grain diameter and lower resistivity. Preferably, no intrinsic grain nucleation occurs within the film during annealing.

In 104, seed crystals 106 are disposed on the substrate 108. Examples of suitable materials for substrates include silicon dioxide (e.g., both porous and fully dense) and glasses (e.g., fluorosilicate glass and organosilicate glass). The seed crystals 106 can be disposed on the substrate 108 with or without a mask. The mask can be a patterned mask. In some cases, the seed crystals 106 are disposed on the substrate 108 through a mask with a repeating pattern, such as a grid. The grid can be a periodic grid. The spacing between seed crystals can be chosen to obtain a desired grain size. In some cases, the spacing between the seed crystals is approximately equal to the desired in-plane grain size. The grain size is typically at least 10 times the film thickness to reduce or prevent contribution from grain boundary scattering to electrical resistivity.

In 110, the seed crystals 106 are encapsulated with an amorphous NiAl layer 112 in a deposition chamber to form an amorphous NiAl precursor film 114. Deposition parameters (e.g., sputtering power, inert gas pressure, co-sputtering from individual targets versus sputtering from a compound target) are varied to achieve the formation of the amorphous NiAl precursor film 114. Forming the amorphous NiAl precursor film 114 can include co-depositing the constituent elements by co-sputtering from separate targets made from the individual constituent elements. Forming the amorphous NiAl precursor film 114 can include depositing the metal alloy by sputtering from a compound target including the two constituent elements. The sputtering power is typically between about 10 W and about 100 W for a target with a 2-inch diameter, with the power scaling with the surface area of the target. Both DC and RF power supply can be used. The inert gas pressure (e.g., Ar pressure) is typically between about 1 mTorr and about 10 mTorr. Contacting the multiplicity of seed crystals with the amorphous metallic alloy layer can include cooling the substrate before depositing the amorphous metallic layer on the substrate. By cooling the seed crystals, the kinetic energy of the Ni and Al atoms is reduced to “freeze” the Ni and Al on contact with the substrate, thereby forming a glassy (amorphous) structure rather than the thermodynamically favored B2 crystal structure. Reducing the kinetic energy can be achieved by cooling the substrate (e.g., with water or liquid nitrogen). Reducing the kinetic energy can also be achieved by interrupting the deposition and flowing an inert gas (e.g., Ar) into the chamber to dissipate the heat generated during the sputter deposition. Deposition can be resumed after the substrate cools to a desired temperature.

In 116, the amorphous NiAl precursor film 114 is annealed to form nucleation sites 118 from the seed crystals 106 that, in 120, yield a metallic film 122 with grains 124 having a large in-plane diameter separated by grain boundaries 126. Annealing can be done in a single stage or in multiple stages. The annealing temperature is typically between 50° C. and 400° C., or between 150° C. and 300° C. Annealing can be achieved in a single stage or in multiple stages. In a single stage annealing, the amorphous NiAl precursor film is heated for a length of time at a selected temperature. In a two-stage implementation of multiple stage annealing, the amorphous NiAl precursor film is heated for a first length of time at a first temperature, followed by a second length of time at a second temperature. In another two-stage implementation of multiple stage annealing, the amorphous NiAl precursor film is heated for a first length of time at a first temperature, allowed to cool, and then heated for a second length of time at a second temperature. The first length of time and the second length of time can be the same or different. In one example of a two-stage annealing process, an amorphous NiAl film is heated at 150° C. for 30 minutes followed by heating at 200° C. for 1 hour. Grain boundaries 126 are shown between grains 124 in FIG. 1B.

When the annealing temperature is chosen appropriately, the in-plane grain diameter to film thickness ratio can exceed 20. Transmission electron microscopy (TEM) can be used to directly image the crystallization process. A preferred annealing temperature obtained by analysis of the TEM images can result in large grain sizes. The annealing temperature can be varied to increase crystal growth while promoting nucleation primarily from the seed crystals rather than randomly in the amorphous film. That is, there is little or no intrinsic or homogeneous grain nucleation in the NiAl film.

The sequence of operations in process 100 depicted in FIGS. 1A and 1B can be varied. Contacting the multiplicity of seed crystals with the amorphous metallic alloy layer can include depositing the amorphous metallic layer on a substrate and depositing the multiplicity of seed crystals on the amorphous metallic layer. Contacting the multiplicity of seed crystals with the amorphous metallic alloy layer can further include encapsulating the multiplicity of seed crystals on the amorphous metallic layer with an additional amorphous metallic layer.

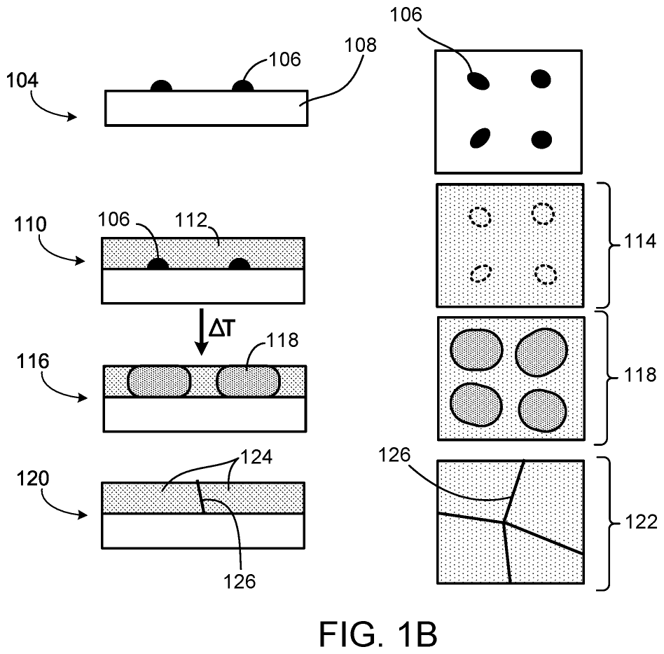

FIG. 2 is a flow chart showing steps in a second process 200 for synthesizing NiAl films with a grain diameter to thickness ratio of at least about 20. In 202, an amorphous NiAl precursor film is deposited on a substrate in a manner similar to that described with respect to FIG. 1A. In 204, the amorphous NiAl precursor film is crystallized by single or multi-stage annealing as described with respect to FIG. 1A to yield the metallic film with grains separated by grain boundaries. The amorphous NiAl film may contain embedded nanocrystallites, which may serve as grain nucleation sites during annealing.

In process 100, an array of widely spaced seed crystals results in preferential nucleation of grains (heterogeneously) in the amorphous precursor film at the locations of the seed crystals, leading to the formation of large grains. In process 200, no seed crystals are used. Rather, the annealing temperature is chosen such that the grains nucleate homogeneously (e.g., randomly) in the film. The average distance between nuclei in process 200 is large, leading to a large average grain size. Process 100 advantageously allows more control of the resulting film characteristics, while process 200 is simpler and involves fewer steps.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A method of forming a metallic film, the method comprising:
contacting a multiplicity of seed crystals with an amorphous metallic alloy layer to form an amorphous precursor film; and
annealing the amorphous precursor film at a temperature between 50° C. and 400° C. to yield the metallic film with grains separated by grain boundaries.

2. The method of claim 1, further comprising disposing the multiplicity of seed crystals on a substrate before contacting the multiplicity of seed crystals with the amorphous metallic alloy layer.

3. The method of claim 2, wherein contacting the multiplicity of seed crystals with the amorphous metallic alloy layer comprises encapsulating the multiplicity of seed crystals between the amorphous metallic alloy layer and the substrate.

4. The method of claim 2, wherein the multiplicity of seed crystals is disposed on the substrate in a predetermined pattern using a mask.

5. The method of claim 2, wherein the substrate comprises a silicon dioxide or a glass.

6. The method of claim 1, wherein contacting the multiplicity of seed crystals with the amorphous metallic alloy layer comprises depositing the amorphous metallic alloy layer on the multiplicity of seed crystals.

7. The method of claim 1, wherein contacting the multiplicity of seed crystals with the amorphous metallic alloy layer comprises:
depositing the amorphous metallic layer on a substrate; and
depositing the multiplicity of seed crystals on the amorphous metallic layer.

8. The method of claim 7, wherein contacting the multiplicity of seed crystals with the amorphous metallic alloy layer further comprises encapsulating the multiplicity of seed crystals on the amorphous metallic layer with an additional amorphous metallic layer.

9. The method of claim 7, further comprising cooling the substrate before depositing the amorphous metallic layer on the substrate.

10. The method of claim 1, wherein contacting the multiplicity of seed crystals with an amorphous metallic alloy layer comprises co-depositing constituent elements of the amorphous metallic alloy layer.

11. The method of claim 10, wherein co-depositing the constituent elements of the amorphous metallic alloy layer comprises co-sputtering from separate targets made from the individual constituent elements of the amorphous metallic alloy layer.

12. The method of claim 1, wherein forming the amorphous metallic alloy layer comprises depositing a metallic alloy.

13. The method of claim 12, wherein depositing the metallic alloy comprises sputtering the metallic alloy from a compound target comprising two constituent elements.

14. The method of claim 1, wherein the amorphous metallic alloy layer comprises NiAl.

15. The method of claim 1, wherein the grains have a diameter to thickness ratio of at least about 20.

16. The method of claim 1, wherein the multiplicity of seed crystals comprises one or more of Cr, Fe, V, and Cu.

17. The method of claim 1, wherein annealing the amorphous precursor film occurs at a temperature between 150° C. and 300° C.

18. The method of claim 1, wherein the annealing occurs in one or more stages.

19. The method of claim 18, wherein the annealing in one of the one or more stages comprises annealing for a length of time at a temperature between 50° C. and 400° C.

20. The method of claim 18, wherein the annealing occurs in at least two stages, and comprises annealing for a first length of time at a first temperature between 50° C. and 400° C. and annealing for a second length of time at a second temperature between 50° C. and 400° C.

21. The method of claim 20, wherein:
the first length of time and the second length of time are the same or different, and
the first temperature and the second temperature are different.

22. The method of claim 20, wherein:
the first length of time and the second length of time are the same or different,
the first temperature and the second temperature are the same or different, and
annealing for the first length of time and annealing for the second length of time is separated by cooling for a length of time.

23. A method of forming a metallic film, the method comprising:
depositing an amorphous precursor film on a substrate; and
annealing the amorphous precursor film at a temperature between 50° C. and 400° C. to yield the metallic film with grains separated by grain boundaries.

24. The method of claim 23, wherein the grains have a diameter to thickness ratio of at least about 20.
